(19) United States
(12) Patent Application Publication
(10) Pub. No.: US 2002/0167802 A1
(43) Pub. Date: Nov. 14, 2002

(54) Printed circuit board

(76) Inventor: Kozo Wada, Osaka (JP)

Correspondence Address: ROSENTHAL & OSHA L.L.P., 1221 MCKINNEY AVENUE, SUITE 2800, HOUSTON, TX, 77010, US

(21) Appl. No.: 10/126,396

(22) Filed: Apr. 19, 2002

(30) Foreign Application Priority Data
Apr. 24, 2001 (JP) P 2001-125677

(51) Int. Cl. H05K 1/00; H05K 1/18; H05K 7/02; H05K 7/06; H05K 7/08

(52) U.S. Cl. 361/748

(57) ABSTRACT

Either one of a high capacity memory 11 and a low capacity memory 12 is placed on a printed circuit board 1. A region where the high capacity memory 11 is placed and another region where the low capacity memory 12 is placed partially overlap each other in the printed circuit board 1. Accordingly, when one of the high capacity memory 11 and the low capacity memory 12 is placed on the printed circuit board 1, the size of wasteful region which is not used for placing the other of the high capacity memory 11 and the low capacity memory 12 can be suppressed. Accordingly, the miniaturization and cost reduction of the printed circuit board 1 can be realized.

### BACKGROUND OF THE INVENTION

The present invention relates to a printed circuit board on which a chip component such as a CPU or a memory is placed.

In the related art, a printed circuit board on which a chip component is placed has been utilized for an electronic device. For example, a control board on which a CPU is placed and a memory board on which an RAM is placed are utilized as the printed circuit board.

Recently, various memories and printed circuit boards are proposed in response to demands for reduction in size and increase in capacity.

For example, a proposal has been made for a semiconductor chip in which lead pins are subjected to wire bonding to make it possible to place lead pins in a transversely inverse form to standard placement of the lead pins (the Unexamined Japanese Patent Application Publication No. Hei10-50757). This semiconductor chip offers an effect in increasing the capacity at low cost.

Further, another proposal has been made for an integrated circuit device in which, when an MIC (microwave integrated circuit) board is mounted on another MIC board formed by vapor depositing a metal, through holes are formed in the lower board or the side surfaces of the respective boards are used so that the back surfaces of the respective upper and lower boards are electrically connected to each other to give commonality to the respective potentials of the back surfaces of the upper and lower boards (the Unexamined Japanese Patent Application Publication No. Hei6-132416).

This integrated circuit device provides effects of miniaturization of an MIC board, increase of the degree of freedom for a pattern, and decrease of the number of boards.

Further, a further proposal has been made for a circuit board in which a circuit pattern is formed on a region where the circuit pattern is hidden under an electronic component after the electronic component such as an LSI is placed on the circuit board (Japanese Patent No. 2857823). This circuit board offers an effect of miniaturization.

Recently, in order to suppress the manufacturing cost of an electronic device, it is considered that a printed circuit board is commonly used among a plurality of electronic devices.

On the other hand, since the electronic devices are not completely identical in function with each other, there may be a case in which chip components placed (mounted) on a printed circuit board for respective electronic devices to be used are made different from each other when the printed circuit board is used commonly between the electronic devices. To take, as an example, the case in which a memory board is used commonly between an electronic device (for example, Digital Versatile Disk (DVD)) of a standard function (hereinafter referred to as a “standard device”) and another electronic device having a function graded upper than the standard device (hereinafter, referred to as an “upper level device”), a memory chip of 16 MB mounted on the printed circuit board comes under the case for the memory board applied to the standard device, while a memory chip of 64 MB mounted on the printed circuit board comes under the case for the memory board applied to the upper level device. On this occasion, although the standard device and the upper level device have different chip components to be mounted on the printed circuit board, the printed circuit board for mounting the chip components can be used in common. Thus, manufacturing cost for the electronic device can be suppressed.

In the related-art printed circuit board 21, as shown in FIG. 4, a region 22 where the 64 MB memory chip is placed and another region 23 where the 16 MB memory chip is placed are formed into separated regions so as not to overlap each other.

On the other hand, as described above, when one of the 16 MB memory chip and the 64 MB memory chip is placed on the printed circuit board 21 in accordance with the device to which the memory chip is applied, the other memory chip is not placed on the printed circuit board 21. In the printed circuit board 21, a region (22 or 23 shown in FIG. 4) is formed for placing the other memory chip which is however not placed in fact. Accordingly, the region for the other memory chip which is in fact not placed is wasteful and there is a problem that the size of the printed circuit board 21 becomes large.

Further, due to increase in size of the printed circuit board 21, there is another problem that the body of the device using the printed circuit board 21 increases accordingly.

### SUMMARY OF THE INVENTION

It is an object of the invention to realize sufficient miniaturization and cost reduction of a printed circuit board commonly used in a plurality of kinds of devices, by forming circuit patterns corresponding to a plurality of chip components on the printed circuit board and by placing a chip component selected from the plurality of chip components onto the printed circuit board.

In order to solve the problems, the printed circuit board according to the invention is provided with the following configuration.

(1) A printed circuit board includes circuit patterns formed thereon correspondingly to a plurality of chip components, one chip component selected from the plurality of chip components being placed on corresponding one of the circuit patterns, wherein the circuit patterns of the respective chip components are formed to be displaced from each other by an amount smaller than a width of each of the chip components.

(2) The circuit patterns corresponding to lead pins in common electrical connection between the chip components are connected electrically.

(3) The plurality of chip components are memories different in storage capacity.

In the configuration, one chip component selected from the plurality of chip components is placed on the board. A circuit pattern is formed for each of the plurality of chip components on the board. The circuit patterns of respective chip components are formed to be displaced from each other by an amount smaller than the width of each of the chip components. By this arrangement, a wasteful region generated due to a chip component in fact not placed on the board can be suppressed so that miniaturization and cost reduction of the board can be realized.

The circuit patterns corresponding to the lead pins in common electrical connection between the chip components are connected electrically. Accordingly, the circuit patterns can be made high in density, so that further miniaturization and further cost reduction of the board can be realized.

### BRIEF DESCRIPTION OF THE DRAWINGS

FIG. 1 is a view showing a printed circuit board according to an embodiment of the invention.

FIGS. 2A and 2B are views showing memories each placed on the printed circuit board according to the embodiment of the invention.

FIG. 3 is a view showing a printed circuit board according to another embodiment of the invention.

FIG. 4 is a view showing a related-art printed circuit board.

FIG. 5A shows an area occupied by one of 16 MB SD-RAM including a foot pattern; and FIG. 5B shows an area occupied by one of 64 MB SD-RAM including a foot pattern.

FIG. 6A shows an area occupied by 16 MB SD-RAM and 64 MB SD-RAM which are arranged simply side by side as in the related art; and FIG. 6B shows an area occupied by 16 MB SD-RAM and 64 MB SD-RAM which partially overlap each other as in the present invention.

FIG. 7A show the printed board mounting the memories of FIG. 6A; and FIG. 7B show the printed board mounting the memories of FIG. 6B.

### DETAILED DESCRIPTION OF THE PREFERRED EMBODIMENTS

A printed circuit board according to an embodiment of the invention will be described hereunder.

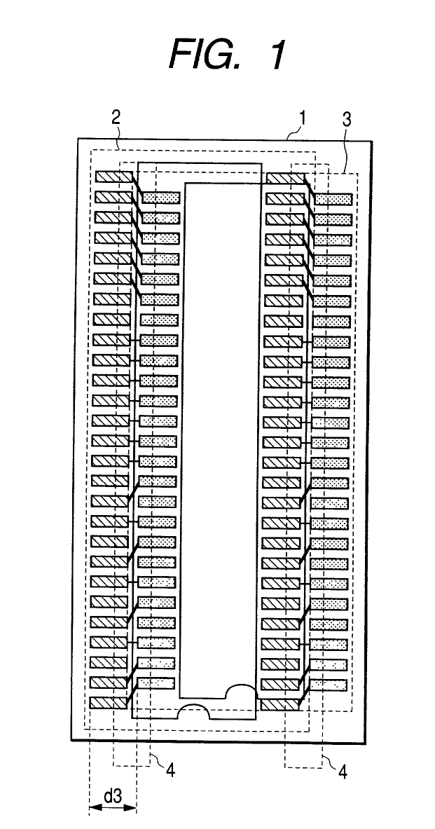

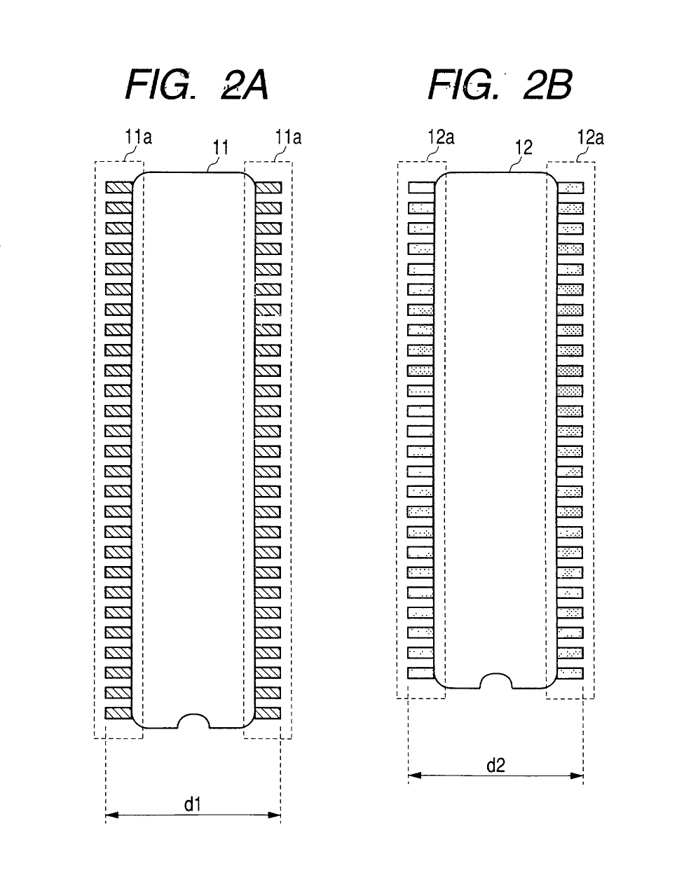

FIG. 1 is a view showing a printed circuit board according to an embodiment of the invention. A printed circuit board 1 of this embodiment is a memory board on which either one of a 64 MB memory 11 (RAM) shown in FIG. 2A and a 16 MB memory 12 (RAM) shown in FIG. 2B is placed (mounted). In order to distinguish the two kinds of memories from each other, the 64 MB memory is refereed to as a high capacity memory 11 and the 16 MB memory is referred to as a low capacity memory 12 hereinafter.

The high capacity memory 11 has 27 lead pins 11a at each side, that is, 54 lead pins 11a in total at the opposite sides, while the low capacity memory 12 has 25 lead pins 12a at each side, that is, 50 lead pins 12a in total at the opposite sides. The high capacity memory 11 and the low capacity memory 12 are made substantially equal to each other in width (d1 and d2 shown in FIGS. 2A and 2B respectively).

On the printed circuit board 1 of this embodiment, a circuit pattern 2 for the high capacity memory 11 and another circuit pattern 3 for the low capacity memory 12 are formed. Further, though not shown in the drawing, a circuit pattern is formed on a back surface of the printed circuit board 1.

The circuit patterns 2 and 3 formed on the front surface of the printer circuit board 1 are formed to be displaced from each other in the direction of the width of the memory 11 (or memory 12) placed on the printed circuit board 1 as shown in FIG. 1. With respect to the portions of the lead pins 11a and 12a in common electrical connection between the high and low capacity memories 11 and 12, circuit patterns corresponding to the portions of the lead pins 11a and 12a are electrically connected by connection patterns 4 in the circuit patterns 2 and 3. Here, the lead pins in common electrical connection include, for example, power source terminals, and address terminals. Incidentally, the circuit patterns to which the portions of the lead pins not in common electrical connection between the light capacity memory 11 and the low capacity memory 12 are connected are independent of each other without being electrically connected by the connection patterns 4.

The amount of widthwise displacement d3 between the circuit patterns 2 and 3 formed on the printed circuit board 1 is smaller than each of the widths d1 and d2 of the high and low capacity memories 11 and 12 respectively. Since the amount of displacement is made larger than either one of the widths of the circuit patterns 2 and 3, the lead pins which are not in common electrical connection between the high and low capacity memories 11 and 12 are not connected directly.

In the printed circuit board 1 having the configuration, the region on which the high capacity memory 11 is placed and the region on which the low capacity memory 12 is placed partially overlap each other. Accordingly, when any one of the high and low capacity memories 11 and 12 is placed on the printed circuit board 1, it is possible to reduce the wasteful region which is not used. Therefore, miniaturization and cost reduction of the printed circuit board 1 can be realized.

Since the region on which the high capacity memory 11 is placed and the region on which the low capacity memory 12 is placed partially overlap with each other, it is possible to reduce the distance between the patterns to which the lead pins in common electrical connection between the high and low capacity memories 11 and 12 are connected. Accordingly, the area required for formation of the connection patterns 4 for connecting these patterns can be suppressed. Therefore, further miniaturization and further cost reduction of the printed circuit board 1 can be realized.

For example, in the case where 16 MB SD-RAM (295.3 mm²) and 64 MB SD-RAM (311.9 mm²) are placed on the printed circuit board, the state is as follows.

As shown in FIG. 6A, the printed circuit board in the related art is occupied by 295.3+311.9=607.2 mm².

On the contrary, as shown in FIG. 6B, the printed circuit board according to the invention is occupied by 295.3+311.9−254.7=352.5 mm², so that the reduction rate is as follows.

(607.2−352.5)/607.2×100=42(%)

Further, the reduction rate for the whole printed circuit board is as follows.

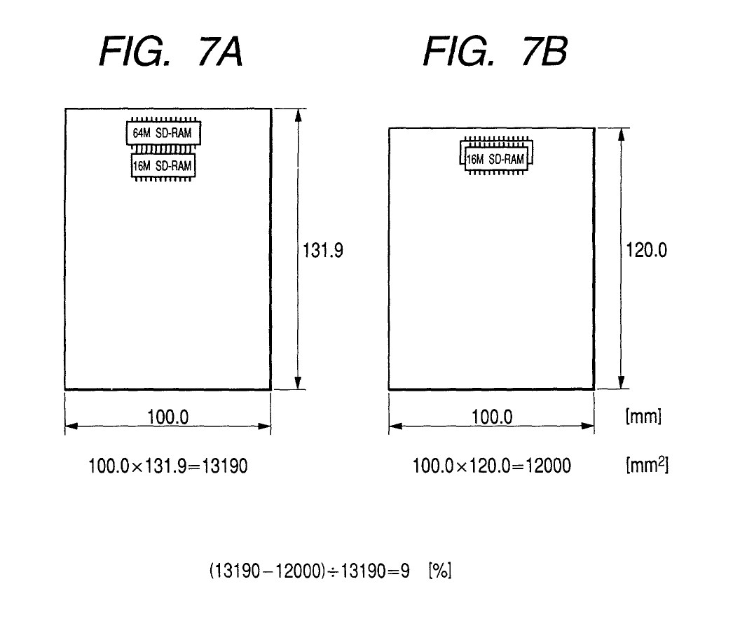

As shown in FIG. 7A, when the memories are arranged simply side by side on the printed circuit board as in the related art, the printed circuit board measures

100×131.9=13190 mm².

On the other hand, as shown in FIG. 7B, when the memories are placed on the printed circuit board according to the invention in the condition that the memories partially overlap each other, the printed circuit board measures

100×120.0=12000 mm².

Therefore, the reduction rate in this case becomes as follows.

(13190−12000)/13190×100=9(%)

Thus, the vertical size of the printed circuit board is reduced by 9%. If the area of the printed circuit board is large, the number of blanks largely increases and it becomes possible to improve the yield.

Further, the number of through holes in the printed circuit board can be reduced.

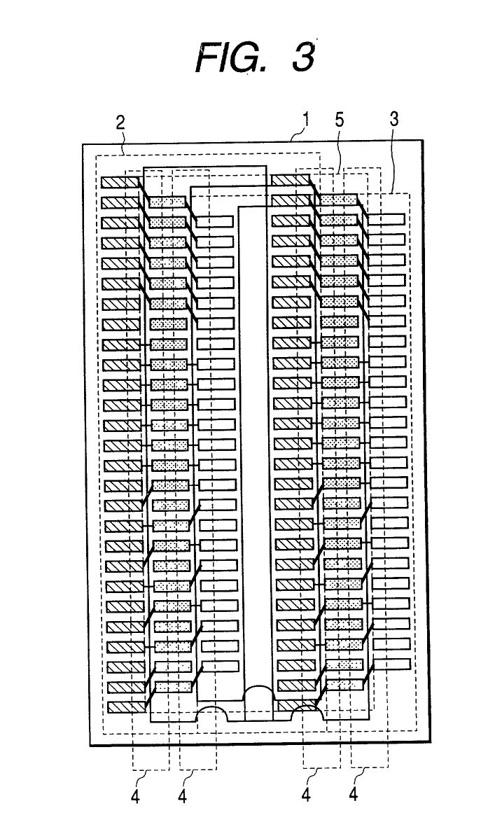

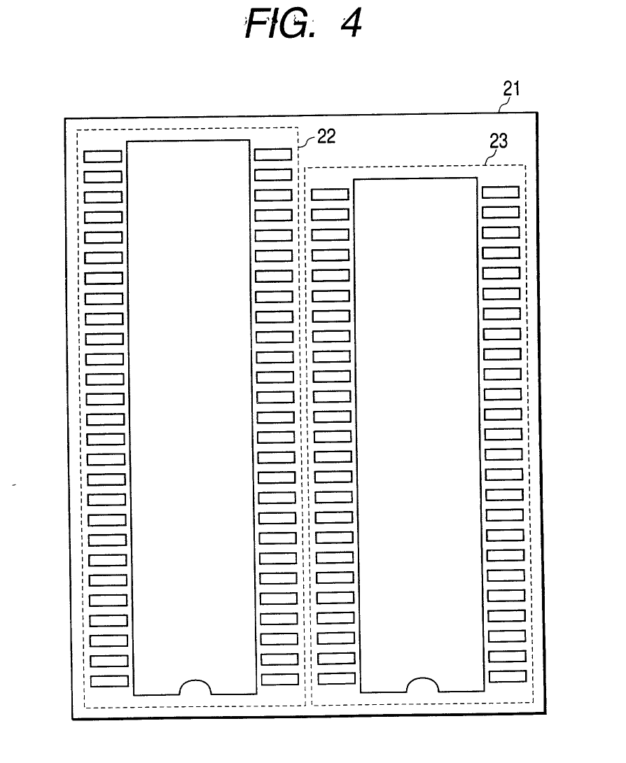

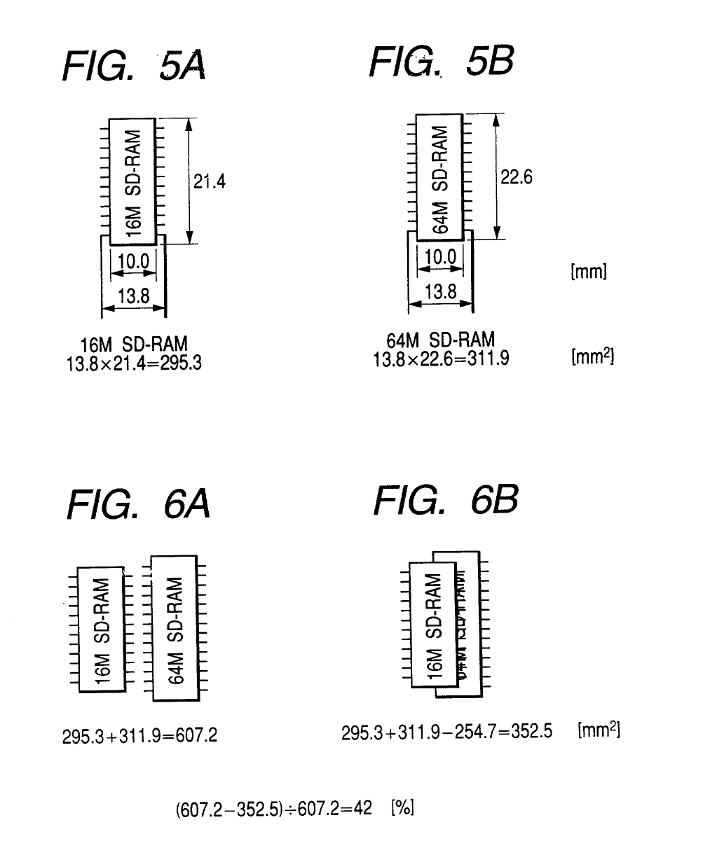

Further, with respect to the arrangement of the 16 MB SD-RAM and the 64 MB SD-RAM, it is preferable to dispose the memories in a manner so that, as shown in FIGS. 1 and 3, the pin positions are disposed vertically symmetrically.

Further, in the high and low capacity memories 11 and 12 placed on the printed circuit board 1, the more arrangement of the terminals is similar, the larger the effect in miniaturization of the printed circuit board 1 is. This is because the area required for formation of the connection patterns 4 can be suppressed. Accordingly, it is preferable that the high capacity memory 11 and the low capacity memory 12 are similar to each other in the arrangement of the lead pins.

Further, as for a printed circuit board 1 on which the high capacity memory 11 is placed and the printed circuit board 1 on which the low capacity memory 12 is placed, the following utilization can be conceived.

For example, it can be conceived that the printed circuit board 1 is commonly used between a device such as a digital versatile disk (DVD) having a standard function and another device graded in function upper than the device having the standard function. Specifically, it can be conceived that a printed circuit board 1 on which a low capacity memory 12 is placed is applied to a DVD having a standard function, while the printed circuit board 1 on which a high capacity memory 11 is placed is applied to another DVD having a high function.

Further, between a standard function device and a high function device with its function graded up by increasing memory capacity, there is hardly any difference in the mechanical configuration, and almost all the difference comes from a portion relating to alteration of software for controlling the operation of the body. Accordingly, almost all the components may be used commonly between a standard function device and a high function device. Thus, manufacturing cost for each of a standard function device and a high function device can be reduced sufficiently.

Description in the embodiment has been made on the case where either one of a high capacity memory 11 and a low capacity memory 12 is placed on a printed circuit board 1. As shown in FIG. 3, however, in addition to the circuit patterns 2 and 3 respectively corresponding to the high and low capacity memories 11 and 12, circuit patterns 4 corresponding to an intermediate capacity memory (for example 32 MB memory) may be provided with widthwise displacement.

Further, although description according to the embodiment of the invention has been made, by way of example, on a printed circuit board 1 on which a memory chip is placed, any other printed circuit board on which any other electronic component such as a CPU is placed is applicable.

As described above, according to the invention, circuit patterns corresponding to respective chip components are formed to be displaced from each other by an amount smaller than the width of each of the chip components. Accordingly, a wasteful region generated due to the chip component which is not placed on the board can be suppressed so that miniaturization and cost reduction of the board can be realized.

Further, since the distance between pins which are used commonly between the chip components can be made short, the circuit patterns can be made high in density. Accordingly, further miniaturization and cost reduction of the board can be realized.

With reduction in cost of the printed circuit board, the production cost of the body of the electronic device by use of the printed circuit board can be suppressed.

What is claimed is:

1. A printed circuit board comprising:
two chip components, and
circuit patterns formed thereon correspondingly to said two chip components, one chip component selected from said two chip components being placed on corresponding one of said circuit patterns, wherein
said circuit patterns of said respective chip components are formed to be displaced from each other by an amount smaller than a width of each of said chip components, and
said circuit patterns corresponding to lead pins in common electrical connection between said chip components are connected electrically.

2. A printed circuit board comprising:
a plurality of chip components, and
circuit patterns formed thereon correspondingly to said plurality of chip components, one selected from said plurality of chip components being placed on corresponding one of said circuit patterns, wherein
said circuit patterns of said respective chip components are formed to be displaced from each other by an amount smaller than a width of each of said chip components.

3. The printed circuit board according to claim 2, wherein
said circuit patterns corresponding to lead pins in common electrical connection between said chip components are connected electrically.

4. The printed circuit board according to claim 2, wherein
said plurality of chip components are memories different in storage capacity.
